(19) United States
(12) Patent Application Publication
(10) Pub. No.: US 2010/0315183 A1
(43) Pub. Date: Dec. 16, 2010

(54) MOUNTING STRUCTURE OF ELECTRONIC CIRCUIT UNIT

(76) Inventor: Satoru Matsuzaki, Miyagi-Ken (JP)

Correspondence Address: BRINKS HOFER GILSON & LIONE, P.O. BOX 10395, CHICAGO, IL, 60610, US

(21) Appl. No.: 12/813,225

(22) Filed: Jun. 10, 2010

(30) Foreign Application Priority Data
Jun. 15, 2009 (JP) 2009-142154

(51) Int. Cl. H03J 1/00; H05K 5/00

(52) U.S. Cl. 334/85; 361/752

(57) ABSTRACT

A mounting structure of an electronic circuit unit includes a circuit board provided with a high frequency circuit, a metallic casing mounted on the circuit board to cover the high frequency circuit, an F type connector fixed to the casing and protruding approximately perpendicularly to the circuit board, and a flexible cable having one end portion connected to the circuit board. In a state in which the F type connector passes through a mounting hole formed through a set-side panel to protrude outward, at least one of the casing and the F type connector is fixed to the set-side panel by a fixing member, and the other end portion of the flexible cable is connected to a mother board.

### CROSS REFERENCE TO RELATED APPLICATION

The present invention contains subject matter related to and claims priority to Japanese Patent Application JP 2009-142154 filed in the Japanese Patent Office on Jun. 15, 2009, the entire content of which is incorporated herein by reference.

### BACKGROUND

1. Technical Field

The present invention relates to a mounting structure of an electronic circuit unit provided with an F type connector, which is suitable as a small-sized tuner unit for receiving a television broadcast.

2. Related Art

Recently, with the spread of slim televisions, there are increasing demands for the miniaturization of a tuner unit for receiving television broadcasts. This type of tuner unit mainly includes a circuit board provided with a high frequency circuit including a part or the entire tuner circuit, a metallic shield cover mounted on the circuit board to cover the high frequency circuit, and an F type connector from which a cable connector for a coaxial cable is detachable. When the tuner unit is mounted on set-side equipment such as a television receiver, a mounting structure is normally employed in which the tuner unit is mounted by soldering a terminal group provided in the circuit board on a wiring pattern of a mother board (set-side board) and the F type connector is inserted through a mounting hole formed through a set-side panel to protrude outward. In relation to the F type connector, an outer shell conductor having a cylindrical shape is fixed to the shield cover by sealing and soldering, and a core wire fitting provided inside the outer shell conductor extends inside the shield cover so as to be electrically connected to the high frequency circuit on the circuit board. Further, the cable connector is fitted into the F type connector, so that an outer conductor and a core wire of the coaxial cable are electrically connected to the outer shell conductor and the core wire fitting of the F type connector, respectively.

As compared with the related art, as an electronic circuit unit provided with the F type connector and suitable for miniaturization, a different type of electronic circuit unit has been proposed in which a small metallic casing is integrally formed with a base end side of the F type connector, and a small circuit board including an LTCC board and the like is provided inside the casing (for example, see Japanese Unexamined Patent Application Publication No. 2005-11604). According to this electronic circuit unit, the height dimension of the casing mounted on the mother board is restricted to be slightly larger than the outer diameter of the F type connector, resulting in the reduction in the height of the electronic circuit unit. Further, since the casing is uprightly mounted on the mother board, an occupation area on the mother board is reduced, so that a mounting area of other parts on the mother board can be easily ensured. In addition, the casing is made of a member equal to that of the shield cover from the functional standpoint, covers the high frequency circuit on the circuit board to electromagnetically shield the high frequency circuit, and fixes the base end of the F type connector by sealing and soldering.

However, according to the above-described electronic circuit unit, if the casing is mounted on the mother board, since the F type connector protrudes approximately parallel to the mother board, the mother board must be arranged approximately perpendicularly to the set-side panel. Thus, in slim televisions and the like, no problems occur when designing the layout in which the F type connector protrudes longitudinally (downward or upward). However, when designing the layout in which the F type connector protrudes transversely, problems may occur in which an arrangement space of the mother board cannot be ensured. In addition, according to the existing electronic circuit unit, even if the size of the casing is reduced as much as possible, it may not be possible to allow an occupation area on the mother board to be smaller than a bottom area of the casing. In this regard, if a mounting density of parts on the mother board increases, problems may occur in which it is difficult to ensure a mounting space of the casing.

### SUMMARY

A mounting structure of an electronic circuit unit includes a circuit board provided with a high frequency circuit, a metallic casing mounted on the circuit board to cover the high frequency circuit, an F type connector fixed to the casing and protruding approximately perpendicularly to the circuit board, and a flexible cable having one end portion connected to the circuit board, wherein in a state in which the F type connector passes through a mounting hole formed through a set-side panel to protrude outward, at least one of the casing and the F type connector is fixed to the set-side panel by a fixing member, and the other end portion of the flexible cable is connected to a mother board.

As described above, if the mounting structure is employed in which the electronic circuit unit is fixed to the set-side panel, instead of the mother board, and the electronic circuit unit is electrically connected to the mother board through the flexible cable, since the protruding direction of the F type connector can be arbitrarily selected with respect to the mother board, even if the mother board is arranged with respect to the set-side panel in any directions, the electronic circuit unit can be mounted without difficulty. For the same reason, in the case of set-side equipment, the relative position relationship between the set-side panel, from which the F type connector protrudes, and the mother board is not limited, resulting in an increase in the degree of freedom for design.

Further, a space on the mother board is necessary for connecting the end portion of the flexible cable, but no space is necessary for mounting the electronic circuit unit, so that an occupation area on the mother board can be significantly reduced, resulting in the obtaining of a high space factor.

### BRIEF DESCRIPTION OF THE DRAWINGS

FIG. 1 is a side view illustrating an electronic circuit unit mounted on set-side equipment in which a mother board is arranged approximately perpendicularly to a panel according to an embodiment of the invention.

FIG. 2 is an enlarged view illustrating main elements of FIG. 1.

FIG. 3 is a front view corresponding to FIG. 1.

FIG. 4 is an exploded perspective view corresponding to FIG. 1.

FIG. 5 is a front view of an electronic circuit unit shown in FIG. 4.

FIG. 6 is a side view illustrating an electronic circuit unit mounted on set-side equipment in which a mother board is arranged approximately parallel to a panel according to a modified example of an embodiment of the invention.

FIG. 7 is a perspective view corresponding to FIG. 6.

### DESCRIPTION OF EXEMPLARY EMBODIMENTS

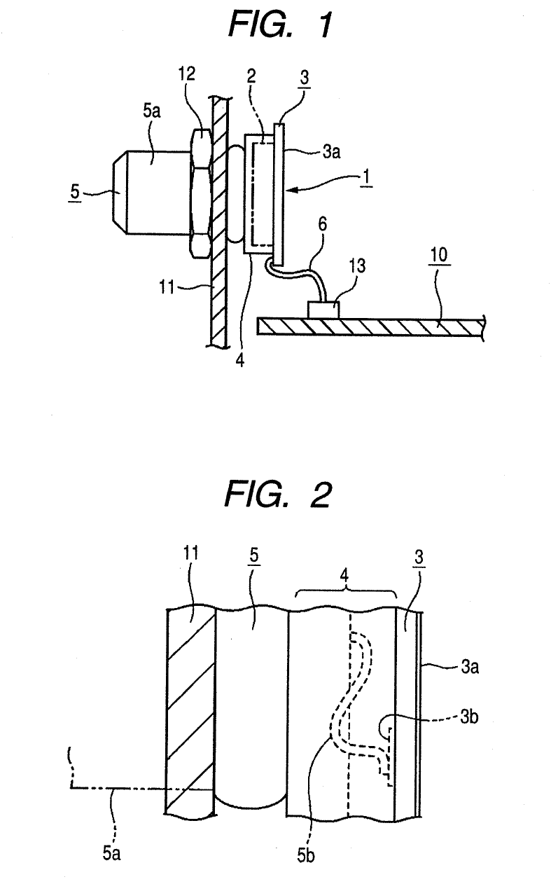

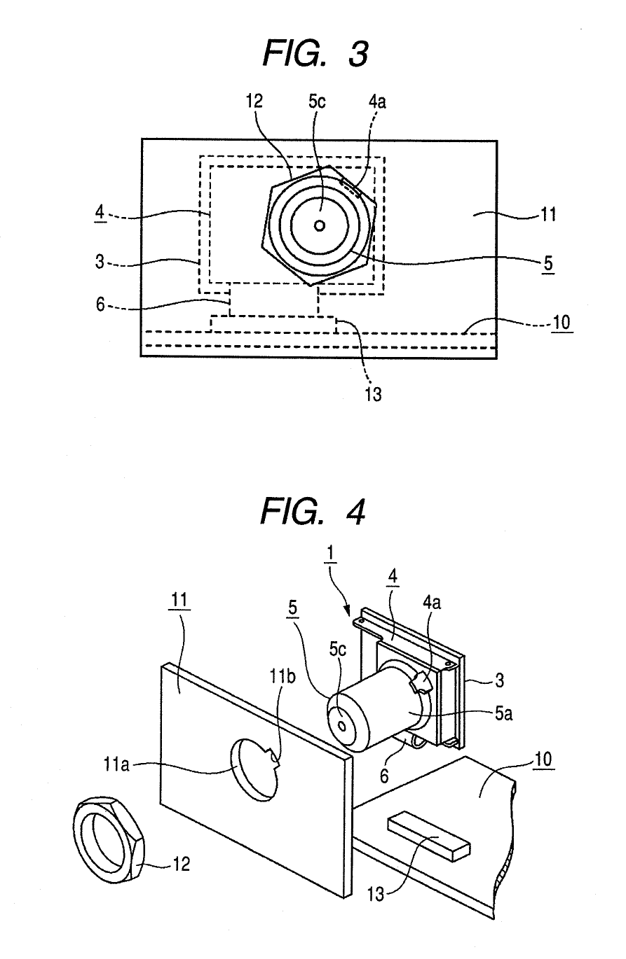

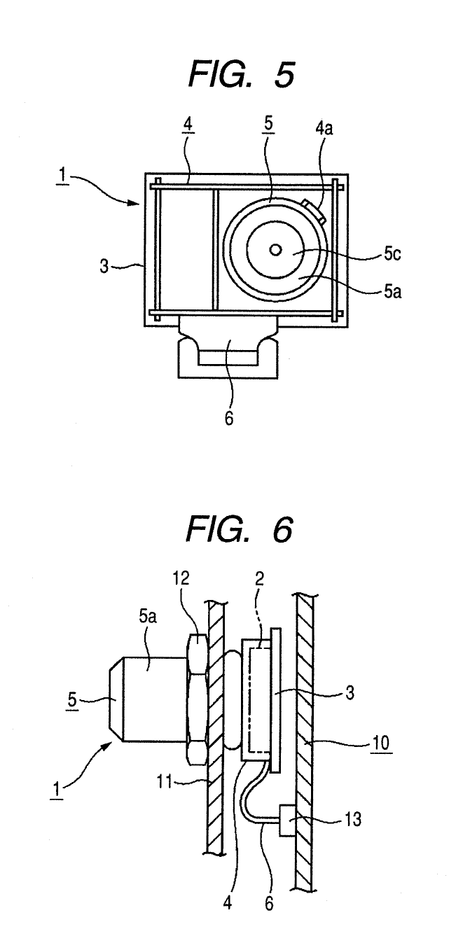

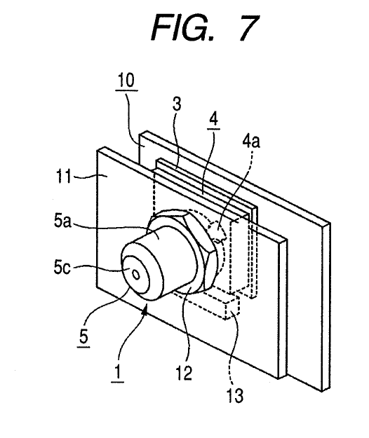

Hereinafter, embodiments of the invention will be described with reference to FIGS. 1 to 7. An electronic circuit unit 1 shown in FIGS. 1 to 7 is a tuner unit for receiving a television broadcast, and is mounted on set-side equipment such as a television receiver provided with a mother board 10 and a panel 11. FIGS. 1 to 4 illustrate the electronic circuit unit 1 mounted on the set-side equipment in which the mother board 10 is arranged approximately perpendicularly to the panel 11, and FIGS. 6 and 7 illustrate the electronic circuit unit 1 mounted on the set-side equipment in which the mother board 10 is arranged approximately parallel to the panel 11.

The electronic circuit unit 1 mainly includes a circuit board 3 provided with a high frequency circuit 2 including a part or the whole of a tuner circuit, a metallic casing 4 mounted on the circuit board 3 to cover the high frequency circuit 2, an F type connector 5 from which a cable connector (not shown) for a coaxial cable is detachable, and a flexible flat cable (FPC) 6 having one end portion connected to the circuit board 3. When the electronic circuit unit 1 is mounted on the set-side equipment, in the state in which the F type connector 5 is inserted through amounting hole 11a (refer to FIG. 4) formed through the panel 11 to protrude outward, a nut member 12 is screwed to the F type connector 5 and the other end portion of the flat cable 6 extending from the circuit board 3 is connected to an FPC connector 13 on the mother board 10. In this way, the electronic circuit unit 1 is fixed to the panel 11 by the nut member 12, and the high frequency circuit 2 is electrically connected to an external circuit of the set-side equipment.

Next, the configuration of the electronic circuit unit 1 will be described in detail. The F type connector 5 has an outer shell conductor 5a having a cylindrical shape, and a thread (not shown) is formed on the outer surface of the outer shell conductor 5a, except for the front end portion thereof. Further, a core wire fitting 5b (refer to FIG. 2) and an insulating member 5c are provided inside the outer shell conductor 5a, and the outer shell conductor 5a is isolated from the core wire fitting 5b by the insulating member 5c. The base end of the outer shell conductor 5a is fixed to the casing 4 by sealing and soldering, so that the F type connector 5 is integrally formed with the casing 4.

The casing 4 is provided with a small cut and raised piece 4a located in the vicinity of the base end of the outer shell conductor 5a. Since the cut and raised piece 4a is inserted into a notched portion 11b (refer to FIG. 4) of the panel 11 so as to be engaged with the panel 11, even if rotational force acts on the electronic circuit unit 1 when the nut member 12 is screwed to the thread of the outer shell conductor 5a, the cut and raised piece 4a is restricted by an inner wall of the notched portion 11b, so that the rotation of the electronic circuit unit 1 is prevented. In addition, the notched portion 11b is formed in the panel 11 in the form of a concave groove obtained by cutting a part of a mounting hole 11a outward in the radial direction.

The casing 4 is formed at a side thereof with an opening end covered by one surface of the circuit board 3, the side being opposite to a side to which the F type connector 5 is fixed, and a ground pattern 3a is formed on substantially the entire surface of the other surface of the circuit board 3. In this way, the high frequency circuit 2 is electromagnetically shielded from the casing 4 by the ground pattern 3a. Further, as shown in FIG. 2, the core wire fitting 5b of the F type connector 5 extends inside the casing 4 to be soldered to an electrode land 3b on the circuit board 3.

In addition, a cable connector for a coaxial cable is fitted into the F type connector 5, so that an external conductor and a core wire of the coaxial cable are electrically connected to the outer shell conductor 5a and the core wire fitting 5b of the F type connector 5, respectively.

When the electronic circuit unit 1 having the above configuration is mounted on the set-side equipment such as a television receiver, the F type connector 5 is inserted through the mounting hole 11a of the panel 11 so as to be screwed into the nut member 12, and the other end portion of the flat cable 6, one end portion of which is connected to the circuit board 3, is connected to the FPC connector 13 on the mother board 10 as described above. The electronic circuit unit 1 is fixed to the panel 11 by allowing the nut member 12 to be screwed to the F type connector 5, so that the electronic circuit unit 1 is stably held even if the electronic circuit unit 1 is not mounted on the mother board 10. Further, the electronic circuit unit 1 is electrically connected to the mother board 10 through the flat cable 6, so that the protruding direction of the F type connector 5 can be arbitrarily selected with respect to the mother board 10. Consequently, even if the mother board 10 is arranged with respect to the panel 11 in any directions, the electronic circuit unit 1 can be mounted without difficulty.

For example, in FIGS. 1 to 4, since the panel 11 corresponds to a bottom plate or a top plate of the set-side equipment, the mother board 10 is arranged approximately perpendicularly to the panel 11. Further, in FIGS. 6 and 7, since the panel 11 corresponds to a side plate, a front plate or a rear plate of the set-side equipment, the mother board 10 is arranged approximately parallel to the panel 11. In any case, the electrical connection between the circuit board 3 of the electronic circuit unit 1 fixed to the panel 11 and the FPC connector 13 on the mother board 10 can be easily and definitely achieved through the flat cable 6.

As described above, since the embodiment of the invention employs the mounting structure in which the electronic circuit unit 1 is fixed to the panel 11, instead of the mother board 10 of the set-side equipment, and the electronic circuit unit 1 is electrically connected to the mother board 10 through the flat cable 6, even if the mother board 10 is arranged with respect to the panel 11 in any directions, the electronic circuit unit 1 can be mounted without difficulty, resulting in the improvement of general versatility. Meanwhile, in the case of the set-side equipment, the relative position relationship between the panel 11, from which the F type connector 5 protrudes, and the mother board 10 is not limited, resulting in an increase in the degree of freedom for design.

Further, according to the embodiment of the invention, no space is necessary for mounting the electronic circuit unit 1 on the mother board 10, so that an occupation area on the mother board 10 can be significantly reduced, resulting in the obtaining of a high space factor. In addition, an electrical connection between the electronic circuit unit 1 and the mother board 10 is completed only by connecting the flat cable 6 to the FPC connector 13, so that connection work between the electronic circuit unit 1 and the mother board 10 can be carried out very easily.

Furthermore, according to the embodiment of the invention, the electronic circuit unit 1 can be fixed to the pane 11 by allowing the nut member 12 to be screwed to the outer shell conductor 5a of the F type connector 5, and the rotation of the electronic circuit unit 1 can be prevented by the engagement between the cut and raised piece 4a and the notched portion 11b, so that mounting work of the electronic circuit unit 1 can be carried out very easily. In addition, the positions of the cut and raised piece 4a and the notched portion 11b, which serve as an anti-rotation member, are not particularly limited. As with the embodiment of the invention, if the notched portion 11b is formed in the form of a concave groove obtained by cutting a part of the mounting hole 11a of the panel 11 outward in the radial direction, preferably, it is not necessary to separately form a hole for the cut and raised piece 4a in the panel 11.

In addition, according to the embodiment of the invention, since the opening end of the casing 4 is covered by one surface of the circuit board 3 and the ground pattern 3a is formed on the other surface of the circuit board 3, even if the circuit board 3 is received in the casing 4, the high frequency circuit 2 can be electromagnetically shielded from the casing 4. Consequently, it is not necessary to form the casing 4 in a large size to the extent that the casing 4 covers the whole of the circuit board 3, so that the electronic circuit unit 1 can be easily reduced in size and weight. However, even in the case of an electronic circuit unit in which a circuit board is received in a casing, it goes without saying that the above effects can be achieved by applying the invention to the electronic circuit unit.

It should be understood by those skilled in the art that various modifications, combinations, sub-combinations and alterations may occur depending on design requirements and other factors insofar as they are within the scope of the appended claims or the equivalents thereof.

What is claimed is:

1. A mounting structure of an electronic circuit unit comprising:
a circuit board provided with a high frequency circuit, a metallic casing mounted on the circuit board to cover the high frequency circuit, an F type connector fixed to the casing and protruding approximately perpendicularly to the circuit board, and a flexible cable having one end portion connected to the circuit board,
wherein in a state in which the F type connector passes through a mounting hole formed through a set-side panel to protrude outward, at least one of the casing and the F type connector is fixed to the set-side panel by a fixing member, and the other end portion of the flexible cable is connected to a mother board.

2. The mounting structure of the electronic circuit unit according to claim 1, wherein the flexible cable is a flat cable.

3. The mounting structure of the electronic circuit unit according to claim 2, wherein a connector for connecting the end portion of the flat cable is mounted on the mother board.

4. The mounting structure of the electronic circuit unit according to claim 1, wherein the fixing member is a nut member which is screwed to the F type connector.

5. The mounting structure of the electronic circuit unit according to claim 4, wherein the casing has a small protrusion that protrudes in the same direction as the F type connector, and the small protrusion is inserted into a notched portion of the set-side panel so as to be engaged with the set-side panel.

6. The mounting structure of the electronic circuit unit according to claim 5, wherein the notched portion is formed in a form of a concave groove defined by a cut part of the mounting hole that extends outward in a radial direction.

7. The mounting structure of the electronic circuit unit according to claim 1, wherein the casing is formed at a side thereof with an opening end covered by one surface of the circuit board, the side being opposite to a side to which the F type connector is fixed, and a ground pattern is formed on the other surface of the circuit board.

8. The mounting structure of the electronic circuit unit according to claim 1, wherein the high frequency circuit is a part of a tuner circuit.

9. The mounting structure of the electronic circuit unit according to claim 1, wherein the high frequency circuit is a whole of a tuner circuit.
